(19) United States
(12) Patent Application Publication
(10) Pub. No.: US 2002/0064919 A1
(43) Pub. Date: May 30, 2002

(54) METHOD OF FABRICATING GATE

(76) Inventor: CHIEN-JUNG WANG, HSINCHU (TW)

Correspondence Address: J.C. PATENTS INC., 4 VENTURE, SUITE 250, IRVINE, CA, 92618, US

(21) Appl. No.: 09/335,632

(22) Filed: Jun. 18, 1999

(30) Foreign Application Priority Data
Apr. 15, 1999 (TW) 88105999

(51) Int. Cl. H01L 21/3205; H01L 21/4763

(52) U.S. Cl. 438/305; 438/592

(57) ABSTRACT

A method for fabricating a gate, wherein a polysilicon gate is formed on a substrate. A first spacer is then formed on a sidewall of the polysilicon gate, while a second spacer is formed on the sidewall of the first spacer. The exposed part of the first spacer is partially removed by performing an anisotropic etching. The metal salicide is formed on the polysilicon gate and the exposed substrate.

### CROSS-REFERENCE TO RELATED APPLICATION

This application claims the priority benefit of Taiwan application serial no. 88105999, filed Apr. 15, 1999, the full disclosure of which is incorporated herein by reference.

### BACKGROUND OF THE INVENTION

1. Field of Invention

The present invention relates to a method of fabricating a semiconductor device. More particularly, the present invention relates to the method of fabricating a gate.

2. Description of Related Art

Conventionally, a spacer is formed on the sidewall of a polysilicon gate to isolate the polysilicon gate from two electrodes of a transistor. However, in the case where the design size of the semiconductor circuits is getting smaller, the resistivity of the circuits is increased without any changes to the materials made. To solve such problem, a method, such as the self-aligned silicide (salicide) process applied to the transistor, is developed. The method involves forming a metal salicide layer on the polysilicon gate and an upper surface of the source/drain regions to reduce the sheet resistance of the polysilicon gate and the source/drain regions.

The known salicide process, such as the application of TiSi₂ on the metal oxide semiconductor (MOS) is to sputter a Ti layer on a MOS transistor, usually after the formation of the gate, the spacer, the source/drain regions of the MOS transistor. A first rapid thermal process (RTP) with a N₂ gas is then performed at a temperature of about 620-680° C., so that the Ti can react with the silicon located below it, forming a C-49 phase TiSi₂ on the surface of the gate, the source, and the drain. The unreactive Ti and TiNₓ are removed by performing a second RTP at a temperature of about 800-900° C., so that the C-49 phase TiSi₂ of high resistivity is modified into the C-54 phase TiSi₂ of low resistivity. Since a photolithographic step is not necessary in the whole process flow, it is therefore an appealing metallization process for forming a contact.

Since, in the RTP for forming TiSi₂, Si is the principal moving species, the moving ability is better with a higher temperature and the reaction would only take place at least about 600° C. to form TiSi₂. As a result, Si which massively diffuse outwards to the Ti layer often reacts with Ti on the surface of the spacer to form TiSi₂. This causes a serious salicide bridge connection where a short circuit occurs between the gate and the source/drain region.

In the deep sub-micron process, the surface area of the polysilicon gate that allows the formation of the metal salicide and the surface area of the source/drain region all become very small. Therefore, the resistivity is not reduced effectively even when the metal salicide is formed on the surface area of the polysilicon gate and the source/drain region.

### SUMMARY OF THE INVENTION

Therefore, the present invention is to provide a fabricating method for a gate to lower the resistivity of the polysilicon gate.

The invention also provides a method for fabricating a gate to increase the reactive surface area of the polysilicon gate for forming the metal salicide.

The invention further provides a method for fabricating a gate, which prevent a salicide bridge connection between the gate and the source/drain region.

According to the objectives of the invention, a method of fabricating a gate comprises steps of forming a polysilicon gate on a substrate, forming a first spacer and a second spacer, both with a width of about 500 Å, on the sidewall of the polysilicon gate outward in sequence. An anisotropic etching is performed to remove the exposed part of the first spacer. A metal salicide is then formed on top of the polysilicon gate and the exposed substrate.

According to the present invention, the resistivity of the gate is reduced by increasing reactive surface area of the gate, while the occurrence of salicide bridge connection between the gate and the source/drain region is still effectively prevented. After part of the first spacer is removed, more surface area of the polysilicon gate around the top edges is exposed. As the exposed surface area of the polysilicon gate increases, the area to grow the metal salicide also increases. The increased metal salicide layer reduces the resistivity of the gate. In addition, a trench, which acts as a wall between the gate and the source/drain region, is increased to prevent the salicide bridge connection.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A-1E are schematic diagram illustrating a process flow for fabricating a gate according to the preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

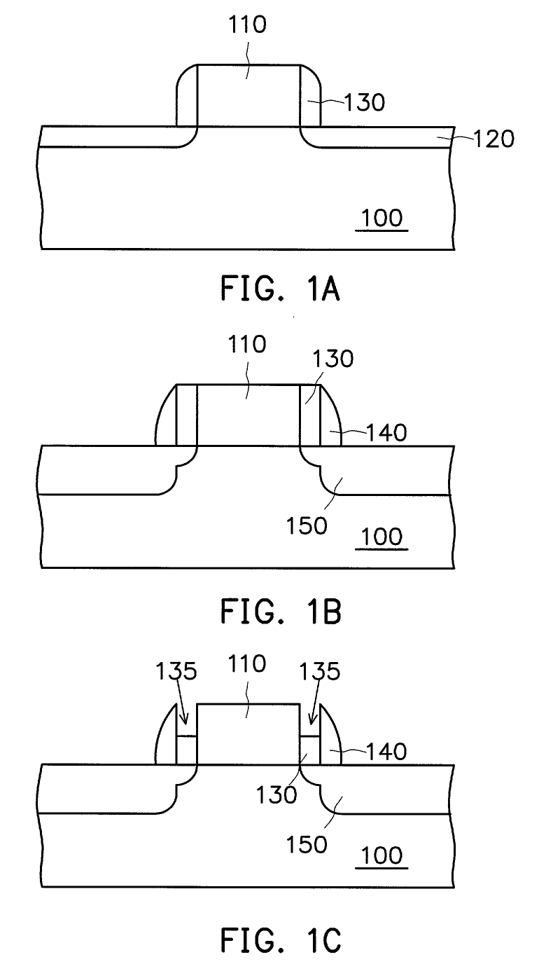

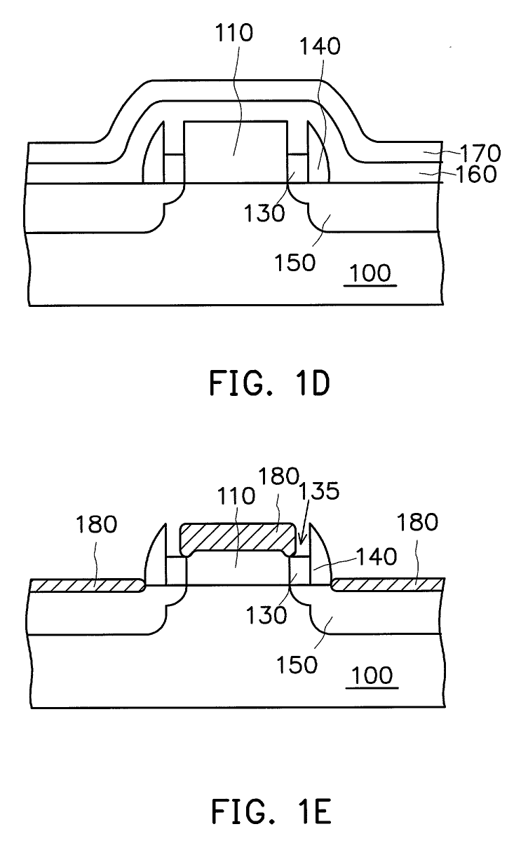

FIGS. 1A-1E are schematic diagram illustrating a process flow for fabricating a gate according to the preferred embodiment of the present invention.

Referring to FIG. 1A, a polysilicon gate 110 is formed on a substrate 100. With the polysilicon gate as a mask, an ion implantation is then performed to form a lightly doped drain (LDD) 120 in the substrate 100 at both sides of the polysilicon gate 110. A first spacer 130 with a width of about 500 Å is formed on the sidewall of the polysilicon gate 110. The method of forming the first spacer 130 involves first forming a dielectric layer conformal to the top profile of the substrate 100 by chemical vapor deposition (CVD), and then etching back by anisotropic etching. The material used for the first spacer 130 is SiNₓ or materials of similar properties.

Referring to FIG. 1B, a second spacer 140 with a thickness of about 500 Å is formed on the outer sidewall of the first spacer 130. With the polysilicon gate 110, the first spacer 130, and the second spacer 140 serving as a mask, an ion implantation step is performed to form source/drain regions 150 in the substrate at both sides of the gate. Preferably, the material for the second spacer 140 has a better selective etching ratio than that for the first spacer 130. For example, the material used for the second spacer 140 is SiOₓ or materials of similar properties when the material for the first spacer 130 is SiNₓ. Accordingly, the method of forming the second spacer 140 involves first forming a dielectric layer conformal to the top profile of the substrate 100 by CVD, and then etching back by anisotropic etching.

Referring to FIG. 1C, an isotropic etching is performed to remove part of the first spacer 130, while a recess 135 is formed between the gate 110 and the second spacer 140 that exposes the top edge of the sidewall of the gate 110. The isotropic etching in this case may include a wet etching, which is performed with 85% concentrated phosphoric acid at about 140-200° C., when the material for the first spacer 130 includes SiNₓ.

Referring to FIG. 1D, a metal layer 160 and a metal nitride layer 170 are formed on the substrate 100 in sequence. The material for the metal layer 160 may include Ti, while the metal layer 160 may be formed by a sputtering process. The material for the metal nitride layer 170, on the other hand, may include TiNₓ, while the metal nitride layer 170 may be formed by a sputtering process or thermal nitridation.

It is understood from the above that the top end of the first spacer is selectively removed to expose an extra surface area around the top edge of the polysilicon gate, due to the material difference between the first spacer and the second spacer. As a consequence, the surface area for the polysilicon gate to react with the metal layer is increased, so that the resistivity of the gate is reduced. The trench structure 135 also prevents Si atom from moving along the surface toward the outside of the second spacer and reacting with the metal atoms from the metal layer to form the metal nitride, which causes the salicide bridge connection between the gate and the source/drain region. Therefore, the application of the present invention can reduce the resistivity of the gate, and in the meantime, prevent the salicide bridge connection between the gate and the source/drain region.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a gate, comprising steps of:
providing a substrate comprising at least a polysilicon gate thereon;
forming a first spacer on a sidewall of the polysilicon gate;
forming a second spacer on the a sidewall of the first spacer;
performing an anisotropic etching to remove a portion of the first spacer not covered by the second spacer; and
forming a metal salicide on top of the polysilicon gate and the exposed substrate.

2. The method of claim 1, wherein the first spacer includes SiNₓ formed by chemical vapor deposition (CVD).

3. The method of claim 1, wherein the second spacer includes SiOₓ formed by CVD.

4. The method of claim 1, wherein the anisotropic etching includes wet etching.

5. The method of claim 1, wherein the step of performing an anisotropic etching further comprises steps of:
forming a metal layer on the substrate;
performing a rapid thermal process (RTP) to have a portion of the metal layer react respectively with the polysilicon gate and the exposed substrate; and
removing the unreactive metal layer.

6. The method of claim 5, wherein the metal layer includes Ti formed by sputtering.

7. The method of claim 5, wherein the step of forming a metal layer on the substrate further comprises forming a metal nitride layer on the metal layer, and wherein the metal nitride layer is removed together with the unreactive metal layer.

8. The method of claim 7, wherein the metal nitride layer is formed by sputtering and thermal nitridation.

9. A method for fabricating a transistor, comprising steps of:
providing a substrate having at least a polysilicon gate thereon;
forming a first spacer on a sidewall of the polysilicon gate;
forming a second spacer on the a sidewall of the first spacer;
performing a ion implantation step to form two source/drain regions in the substrate at both sides of the gate;
performing an anisotropic etching to remove a portion of the first spacer not covered by the second spacer; and
forming a metal salicide on top of the polysilicon gate and the two source/drain regions.

10. The method of claim 9, wherein the first spacer includes SiNₓ formed by chemical vapor deposition (CVD).

11. The method of claim 9, wherein the second spacer includes SiOₓ formed by CVD.

12. The method of claim 9, wherein the anisotropic etching includes wet etching.

13. The method of claim 9, wherein the step of forming a metal salicide further comprises steps of:
forming a Ti layer on the substrate;
performing a rapid thermal process (RTP) to have a portion of the Ti layer react respectively with the polysilicon gate and the two source/drain regions; and
removing the unreactive Ti layer.

14. The method of claim 13, wherein the step of forming a Ti layer includes a sputtering process.

15. The method of claim 13, wherein the step of forming a Ti layer further comprises a step of forming a TiNₓ layer on the Ti layer, and wherein the TiNₓ layer is removed along with the unreactive Ti layer.

16. The method of claim 15, wherein the TiNₓ layer is formed by sputtering and a thermal nitridation.
